(19) United States
(12) Patent Application Publication
(10) Pub. No.: US 2025/0309091 A1
(43) Pub. Date: Oct. 2, 2025

(54) LIQUID METAL SOCKET INTERCONNECTS WITH POOLED WELLS

(71) Applicant: Intel Corporation, Santa Clara, CA (US)

(72) Inventors: Karumbu Nathan Meyyappan, Portland, OR (US); Srikant Nekkanty, Chandler, AZ (US)

(73) Assignee: Intel Corporation, Santa Clara, CA (US)

(21) Appl. No.: 18/622,746

(22) Filed: Mar. 29, 2024

(51) Int. Cl. H01L 23/498; H01L 21/48; H01R 12/71; H01R 13/03; H05K 1/18

(52) U.S. Cl. CPC H01L 23/49866; H01L 21/4867; H01L 23/49833; H01L 23/49838; H01R 12/716; H01R 12/718; H01R 13/03; H05K 1/181; H05K 2201/10189

(57) ABSTRACT

In one embodiment, an integrated circuit assembly includes a liquid metal (LM)-based interconnect with pooled or interconnected wells. The pooled wells may interconnect multiple pins of the LM-based interconnect.

### BACKGROUND

Liquid metal (LM) interconnect architectures may utilize Gallium (Ga) or Ga alloy liquid metals to provide separable and reusable interconnections for integrated circuit devices, e.g., in lieu of traditional solder-based interconnection technologies (e.g., ball grid arrays) that are substantially permanent in their current implementations.

### BRIEF DESCRIPTION OF THE DRAWINGS

FIGS. 1A-1C illustrate an example integrated circuit device assembly that utilizes a liquid metal (LM) socket interconnect without pooled wells.

FIGS. 2A-2C illustrate an example integrated circuit device assembly that utilizes a LM socket interconnect with pooled wells in accordance with embodiments of the present disclosure.

FIGS. 3A-3C illustrate another example integrated circuit device assembly that utilizes a LM socket interconnect with pooled wells in accordance with embodiments of the present disclosure.

FIGS. 4A-4C illustrate yet another example integrated circuit device assembly that utilizes a LM socket interconnect with pooled wells in accordance with embodiments of the present disclosure.

FIGS. 5A-5C illustrate example alternate embodiments of the integrated circuit device assemblies in accordance with embodiments of the present disclosure.

FIGS. 6A-6B illustrate an example squeegee filling process for filling an interposer with LM in accordance with embodiments of the present disclosure.

FIGS. 7A-7B illustrate an example injection filling process for filling an interposer with LM in accordance with embodiments of the present disclosure.

FIG. 8 is a top view of a wafer and dies that may be included in a microelectronic assembly, in accordance with any of the embodiments disclosed herein.

FIG. 9 is a cross-sectional side view of an integrated circuit device that may be included in a microelectronic assembly, in accordance with any of the embodiments disclosed herein.

FIG. 10 is a block diagram of an example electrical device that may include a microelectronic assembly, in accordance with any of the embodiments disclosed herein.

### DETAILED DESCRIPTION

Embodiments herein include integrated circuit device assemblies that utilize liquid metal (LM)-based interconnects, and in particular, include pooled LM wells. The LM-based interconnects may implement wells (which may also referred to as reservoirs) that include a LM alloy, e.g., a LM comprising Gallium such as a Gallium-based LM alloy, between the backside of an integrated circuit package and a socket of a circuit board (e.g., a main board or motherboard). The LM-based interconnect can provide a low insertion force and low contact resistance interface between pads of the package substrate and contacts (e.g., metal pins) of the socket. In certain architectures, the LM is filled into wells that are attached to an integrated circuit package, e.g., in an interposer-like device. A socket may have pins that are inserted into the wells when the package is attached, causing the pins and LM to be in physical contact (and thus, electrical connection) with one another. The package can later be removed to allow for attachment to another socket, or to allow for another package to be attached to the same socket (e.g., when the package is defective).

Though highly conductive, LM might still not be as conductive as traditional solder materials (e.g., LM may have approximately 50% the conductivity of typical solder materials), which means higher resistances seen in the interconnects. One downside of higher resistance could be a need for an increased pin count for certain pins, e.g., power delivery pins. Though LM-based interconnects might be sufficient for current high speed interconnect standards, future generations of such standards may require interconnects with even lower resistance/higher conductivity.

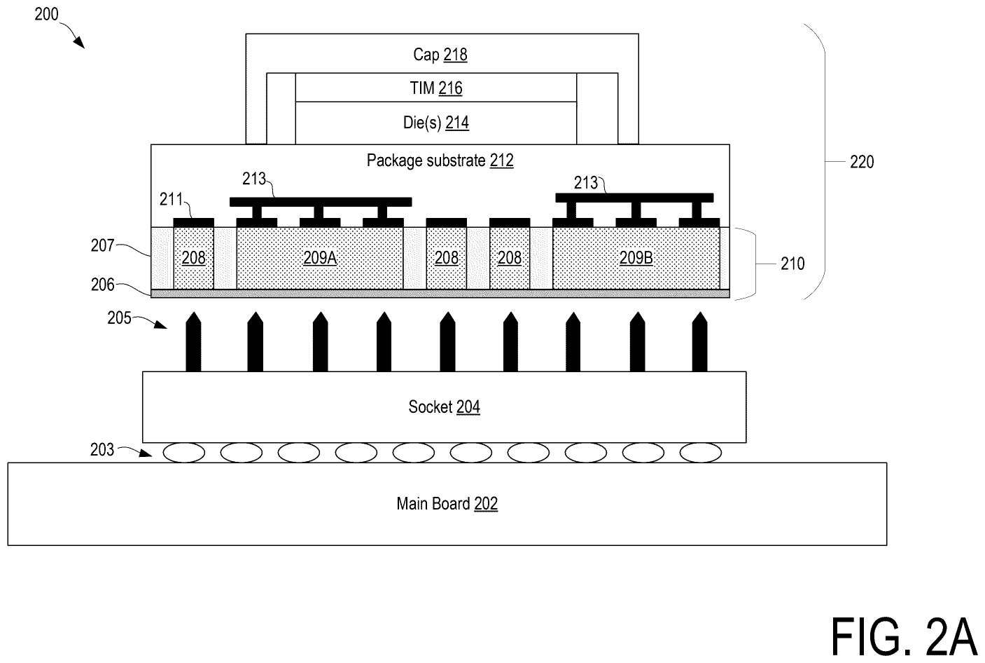

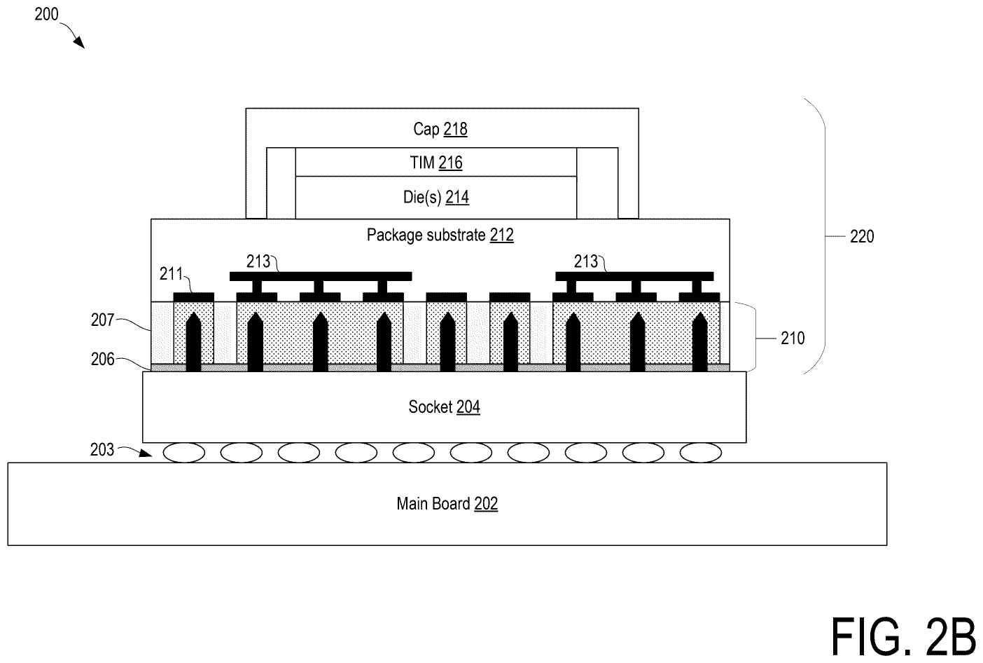

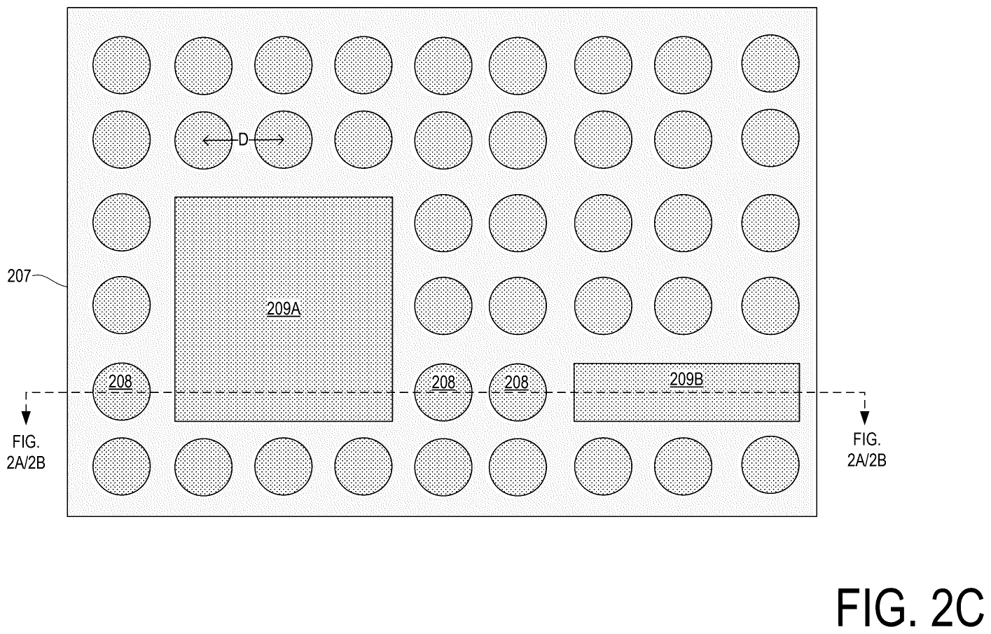

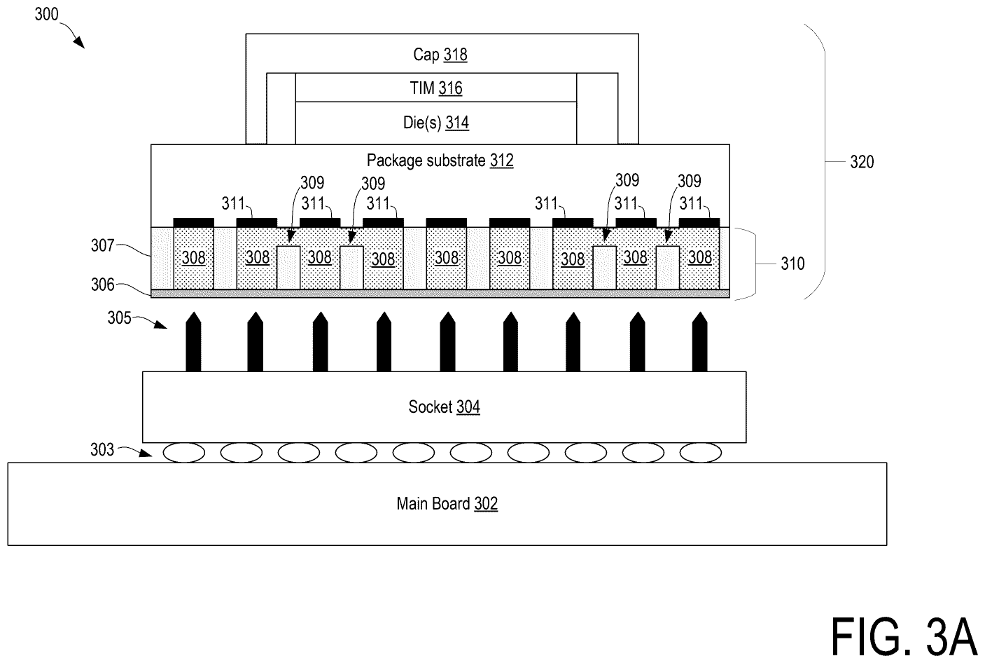

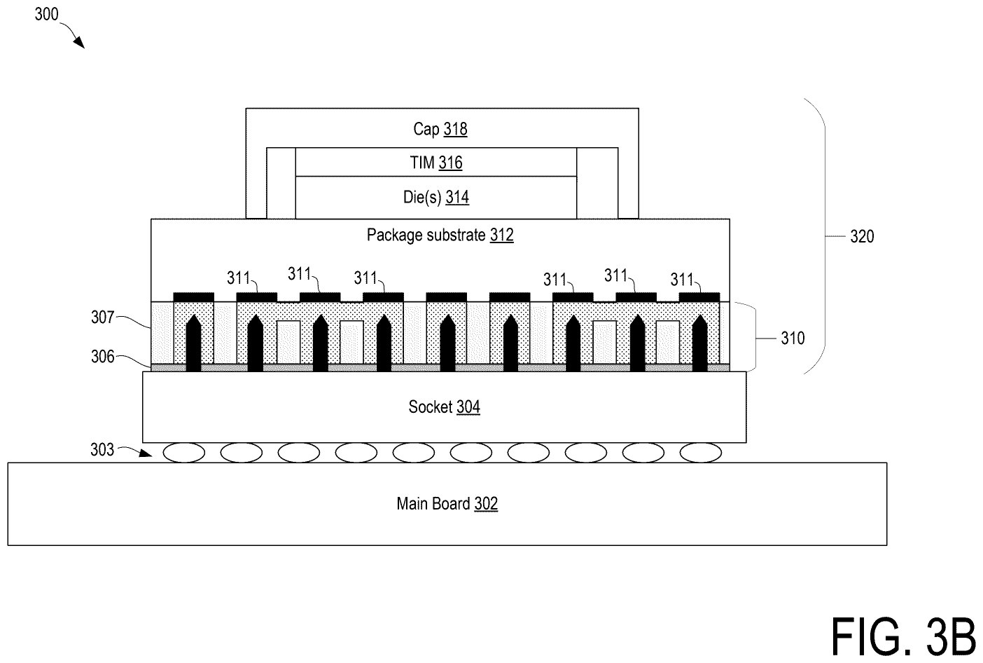

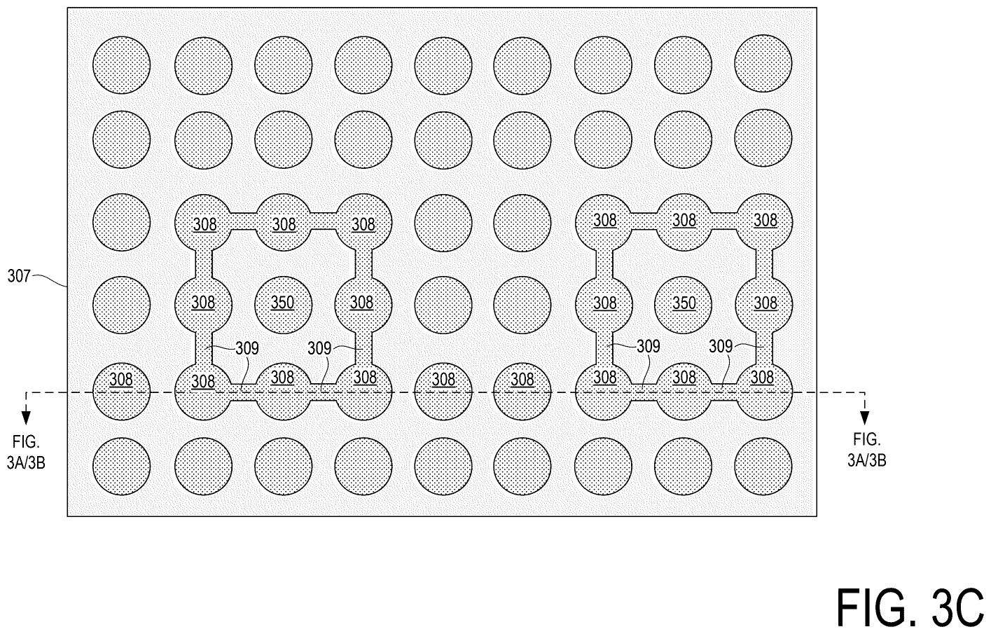

Accordingly, aspects of the present disclosure relate to LM-based interconnects with LM wells that are pooled to reduce bulk resistance. As used herein, pooled wells may refer to the use of a single LM well for interconnecting multiple pads/pins of a package (e.g., as shown in FIGS. 2A-2C) or to connecting certain discrete LM wells together via channels (e.g., as shown in FIGS. 3A-3C). Pooling of LM wells as described herein can significantly reduce the bulk resistance of LM interconnects, which may prove crucial as technology scales down further and the LM well dimensions reduce (since the reduced cross sections will increase bulk resistance). In addition, LM well pooling can help with shielding and reducing electromagnetic interference in addition to providing reduced resistance in the interconnect. Further, the ability to connect or pool wells in an LM-based interconnect can provide degrees of freedom to manage high-speed performance constraints for certain applications. Moreover, because LM technology is infinitely compliant and does not require any reflow, it may be easier to pool the connections to aid performance versus solder-based interconnects.

Although the examples below are described as having LM wells being formed in a interposer/layer coupled to a package substrate, embodiments herein can be implemented in other manners as well. For example, in some embodiments, the LM wells are instead formed in or coupled to the socket, and package substrate includes pins coupled thereto to be placed into the LM wells of the socket.

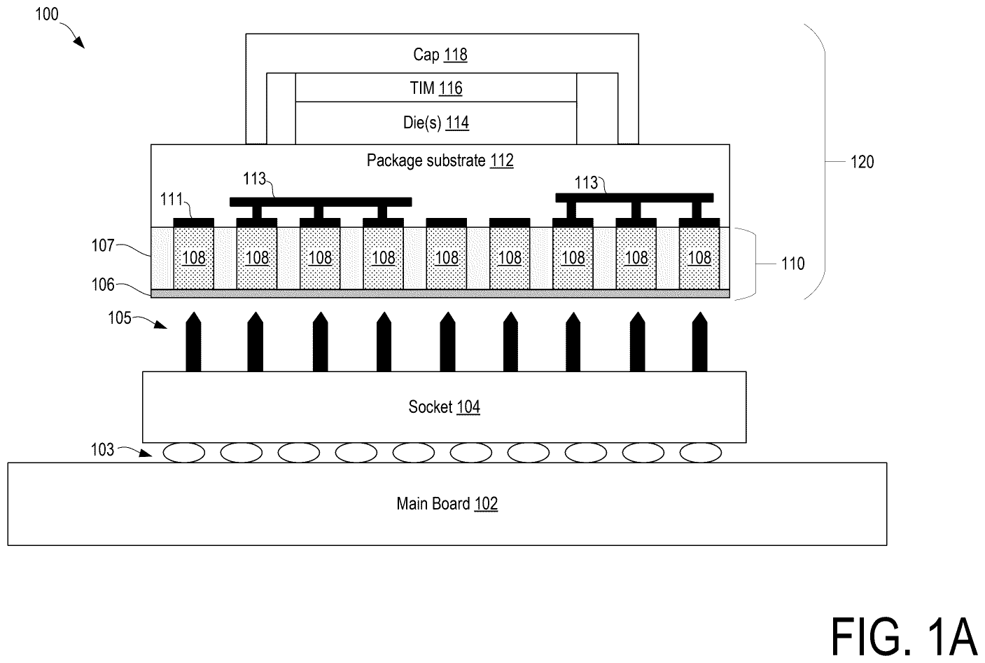

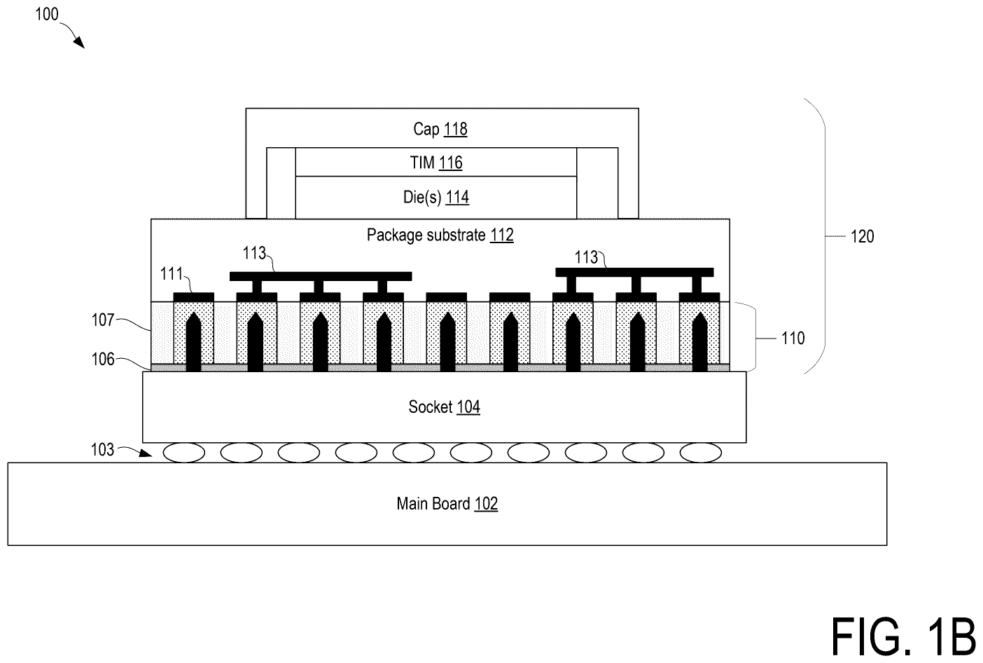

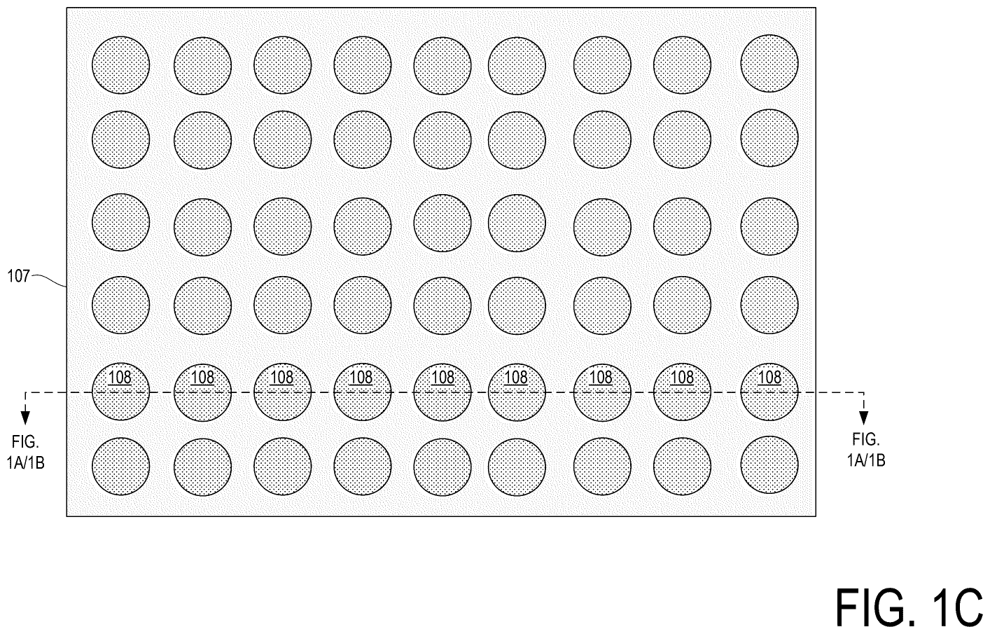

FIGS. 1A-1C illustrate an example integrated circuit device assembly 100 that utilizes a liquid metal (LM) interconnect without pooled wells. In the example shown, the assembly 100 includes a main circuit board 102 (or main board 102), which may be a motherboard, system board, etc. The main board 102 may be a printed circuit board (PCB) including multiple metal (or interconnect) layers separated from one another by layers of dielectric material and interconnected by electrically conductive vias. The individual metal layers comprise conductive traces. Any one or more of the metal layers may be formed in a desired circuit pattern to route electrical signals (optionally in conjunction with other metal layers) between the components coupled to the main board 102. In other embodiments, the main board 102 may be or include a non-PCB substrate.

A LM-compatible socket 104 is coupled to the main board 102 via solder bumps 103. The bumps 103 may be formed using Tin, Tin alloys, or any other suitable solder material. In some embodiments, the LM-compatible socket 104 may be coupled to the main board 102 via other mechanisms.

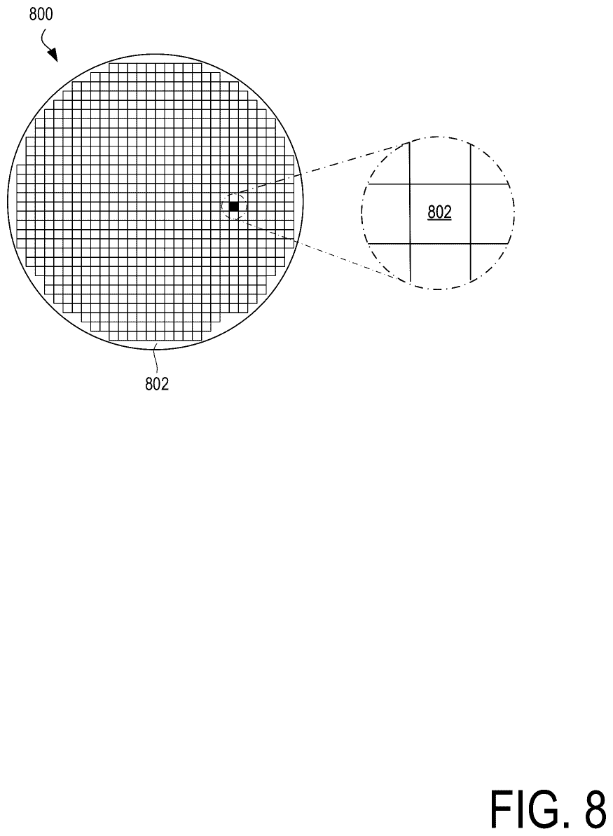

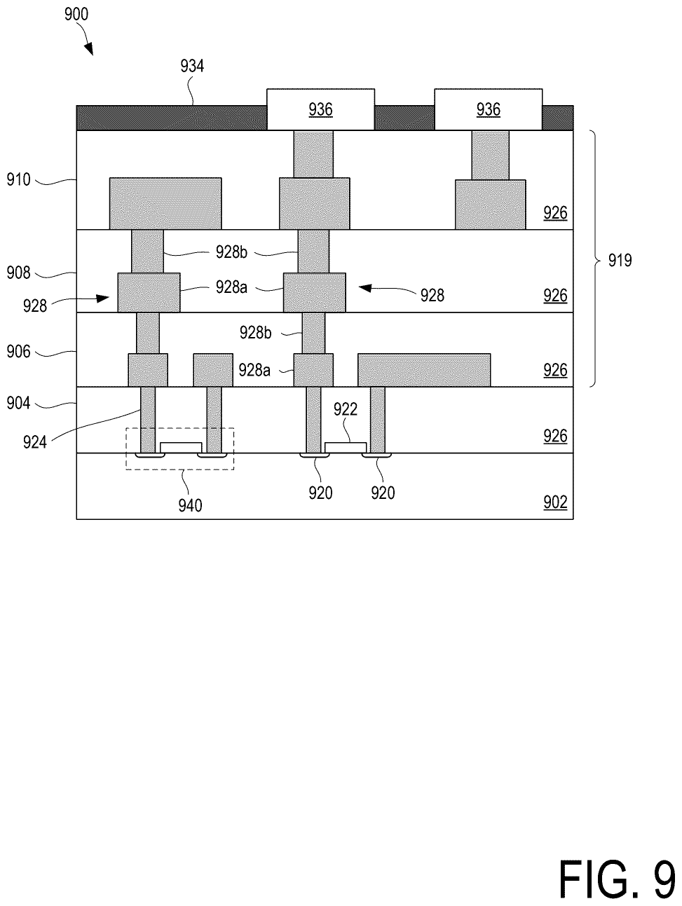

The assembly 100 also includes an integrated circuit device package 120 that includes a package substrate 112, an integrated circuit die 114 coupled to the package substrate 112, a thermal interface material (TIM) 116 on the die 114, and a cap 118 enclosing the die 114 and TIM 116 on the top surface of the package substrate 112. The die 114 may be a packaged or unpacked integrated circuit product that includes one or more integrated circuit dies (e.g., the die 802 of FIG. 8 or the integrated circuit device 900 of FIG. 9) and/or one or more other suitable components. The die 114 can comprise one or more computing system components, such as one or more processor units (e.g., system-on-a-chip (SoC), processor core, graphics processor unit (GPU), accelerator, chipset processor), I/O controller, memory, or network interface controller. In some embodiments, the die 114 can comprise one or more additional active or passive devices such as capacitors, decoupling capacitors, resistors, inductors, fuses, diodes, transformers, sensors, electrostatic discharge (ESD) devices, and memory devices. In addition to comprising one or more processor units, the die 114 can comprise additional components, such as embedded DRAM, stacked high bandwidth memory (HBM), shared cache memories, input/output (I/O) controllers, or memory controllers. Any of these additional components can be located on the same integrated circuit die as a processor unit, or on one or more integrated circuit dies separate from the integrated circuit dies comprising the processor units. These separate integrated circuit dies can be referred to as “chiplets”. In embodiments where an integrated circuit component comprises multiple integrated circuit dies, interconnections between dies can be provided by the package substrate, one or more silicon interposers, one or more silicon bridges embedded in the package substrate (such as Intel® embedded multi-die interconnect bridges (EMIBs)), or combinations thereof.

The package 120 also includes an interposer housing 110 that includes a layer 107 with holes therein that define LM wells 108 in which a LM (e.g., a Ga-based LM) resides and a barrier 106 to prevent the LM from leaving the wells 108. The wells 108 are adjacent respective metal pads 111 of the package substrate, allowing the pads 111 to be accessible through the wells 108. In the example shown, the wells 108 are cylindrical, with a circular cross-section as shown in FIG. 1C; however, the wells 108 may be formed in another manner, e.g., with square or rectangular cross-sections. The package substrate 112 includes a set of metal contact pads 111 formed on the backside of the substrate, i.e., on the side opposite from the die 114. The wells 108 are defined as openings or holes within the layer 107, and extend from the substrate-side of the layer 107 (the top side in FIGS. 1A-1B) to the socket-side of the layer 107 (the bottom side in FIGS. 1A-1B). As used herein, an opening, hole, or well being “defined around” a conductive contact may refer to the opening's defining structures being formed adjacent to the conductive contact such that the conductive contact is accessible via the opening, hole, or well. This can include the structures of the opening, hole, or well surrounding all or a portion of the conductive contact. For instance, in the example shown, the walls of the wells 108 are defined around the pads 111 such that the pads 111 would be accessible from within the wells 108, e.g., LM within the wells can be in physical contact with the pads 111 when inside the wells 108 as shown. In some embodiments, the wells 108 may be defined around the pads 111 such that the entire pad 111 is accessible from within the well 108 (e.g., a cross-sectional area of the pad 111 is smaller or equal to the cross-sectional area of the well 108), while in other embodiments, the wells may be defined around the pads 111 such that only a portion of the pad 111 is accessible from within the well 108 (e.g., a cross-sectional area of the pad 111 is larger than the cross-sectional area of the well 108).

The metal pads 111 allow for electrical connections between the main board 102 and the die 114, via the socket 104, the LM in the wells 108 of the interposer housing 110, and traces within the package substrate 112. The package substrate 112 further includes interconnect traces 113 that connect multiple pads 111 together.

As shown, the LM-compatible socket 104 includes a set of pins 105. The pins 105 enable an electrical connection between the main board 102 and the die 114, through the LM in wells 108, the pads 111, and conductive paths in the package substrate 112. The sharp ends of the interconnect pins 105 may be useful in piercing the barrier 106, causing the pins 105 to be in physical contact with the LM in the wells 108 (as shown in FIG. 1B), and to accordingly be in electrical contact with the metal pads 111 of the package substrate 112.

FIGS. 2A-2C illustrate an example integrated circuit device assembly 200 that utilizes a LM socket interconnect with pooled wells 209 in accordance with embodiments of the present disclosure. The components of the example assembly 200 may be the same as or similar to the same respective components described above with respect to the assembly 100 of FIGS. 1A-1B, except that the layer 207 includes pooled LM wells 209. That is, the main board 202 may be implemented in the same or similar manner as the main board 102, the bumps 203 may be implemented in the same or similar manner as the bumps 103, the socket 204 may be implemented in the same or similar manner as the socket 104, the pins 205 may be implemented in the same or similar manner as the pins 105, the layer 207 may be implemented in the same or similar manner as the layer 107, the package substrate 212 may be implemented in the same or similar manner as the package substrate 112 (with the pads 211 of the substrate 212 being implemented in the same or similar manner as the pads 111), the die 214 may be implemented in the same or similar manner as the die 114, the TIM 216 may be implemented in the same or similar manner as the TIM 116, and the cap 218 may be implemented in the same or similar manner as the cap 118.

In the example shown, the integrated circuit device package 220 includes an interposer housing 210 with a layer 207 that includes cylindrical LM wells 208, which are covered by a barrier 206. The LM wells 208 are similar to the wells 108 of FIGS. 1A-1C in that the each well 208 is defined around one corresponding pad 211 of the substrate 212 (i.e., the pads 211 are accessible through the well 208 defined in the layer 207). The LM inside the wells 208 are accordingly conductively coupled to one of the pads 211, e.g., in physical contact with the pads 211 in the example shown. The package 220 also includes pooled LM wells 209 with rectangular cross-sections, with each of the pooled wells 209 being defined around multiple pads 211 so that the LM inside each of the wells 209 is conductively coupled to multiple of the pads 211. In particular, the pooled LM well 209A is defined around nine pads 211 (as shown in FIG. 2C) and thus interconnects nine pads/pins of the LM-based interconnect, and the pooled LM well 209B is defined around three pads 211 of the substrate 212 and thus interconnects three pads/pins of the LM-based interconnect. Although the non-pooled wells 208 are shown as having circular cross-sections, they may be formed in another manner, e.g., with square or rectangular cross-sections. Similarly, although the pooled LM wells 209 are shown as having rectangular cross-sections, they may be formed in another manner, e.g., with a circular or irregular cross-section.

Where the distance between the center of the non-pooled wells 208 is D (as shown in FIG. 2C), the pooled well 209A may provide an approximately 11× increase in the cross-sectional area of LM as compared with the example shown in FIG. 1C (e.g., the area of the well 209A being 9D² as compared with πD²/4 for nine non-pooled wells 208), significantly reducing the resistance for the electrical connections (e.g., those connected by traces 213 vs. those connected by traces 113 in the example shown in FIGS. 1A-1C). Pooling in this manner may be helpful, for example, where power or ground connections are located close to one another in the package substrate 212. That is, the pooled wells can be defined around common power rail connections (e.g., Vcc, Vss, ground, etc.) so that the LM interconnections have reduced resistance.

FIGS. 3A-3C illustrate another example integrated circuit device assembly 300 that utilizes a LM socket interconnect with pooled wells in accordance with embodiments of the present disclosure. The components of the example assembly 300 may be the same as or similar to the same respective components described above with respect to the assembly 100 of FIGS. 1A-1B, except that the layer 307 includes LM wells 308 that are pooled together via channels 309. In the example shown, the channels 309 are adjacent the substrate 312 and not the barrier 306 on the opposite side of the layer 307; however, the channels 309 may be formed in the layer 307 in another manner. The wells 308 are holes or openings within the layer 307 that are defined around respective pads 311 of the substrate 312. For instance, in the example shown, the wells 308 are substantially circular cross-sectioned openings, but perhaps might not be considered fully circular in their cross-section as shown in FIG. 3C due to the channels 309 interconnecting the wells 308. Accordingly, the wells 308 can be said to be defined substantially around respective pads 311 of the substrate 312, since the walls of the layer 307 that define the wells 308 do not entirely surround the pads 311.

As in the previous example, the main board 302 may be implemented in the same or similar manner as the main board 102, the bumps 303 may be implemented in the same or similar manner as the bumps 103, the socket 304 may be implemented in the same or similar manner as the socket 104, the pins 305 may be implemented in the same or similar manner as the pins 105, the layer 307 may be implemented in the same or similar manner as the layer 107, the package substrate 312 may be implemented in the same or similar manner as the package substrate 112 (with the pads 311 of the substrate 312 being implemented in the same or similar manner as the pads 111), the die 314 may be implemented in the same or similar manner as the die 114, the TIM 316 may be implemented in the same or similar manner as the TIM 116, and the cap 318 may be implemented in the same or similar manner as the cap 118.

In the example shown, the integrated circuit device package 320 includes an interposer housing 310 with a layer 307 that includes multiple cylindrical LM wells 308 covered by a barrier 306. The LM wells 308 are similar to the wells 108 of FIGS. 1A-1C, and certain of the LM wells 308 are joined or pooled together via channels 309 within the layer 307. Embodiments such as the one shown in FIGS. 3A-3C might be useful to provide shielding to certain pins of the LM-interconnect, e.g., to prevent electromagnetic interference. For instance, in the example shown, the pins that would connect to the wells 350 as shown in FIG. 3C may be shielded by the surrounding wells 308 that are pooled via channels 309. As in the previous example, although the wells 308 are shown as having circular cross-sections, they may be formed in another manner, e.g., with square or rectangular cross-sections. Similarly, although the channels 309 are shown as having a particular cross-section, width with respect to the wells, or depth within the layer 307 (e.g., not being as deep as the entire depth of the layer 307), the channels 309 may be formed in another manner.

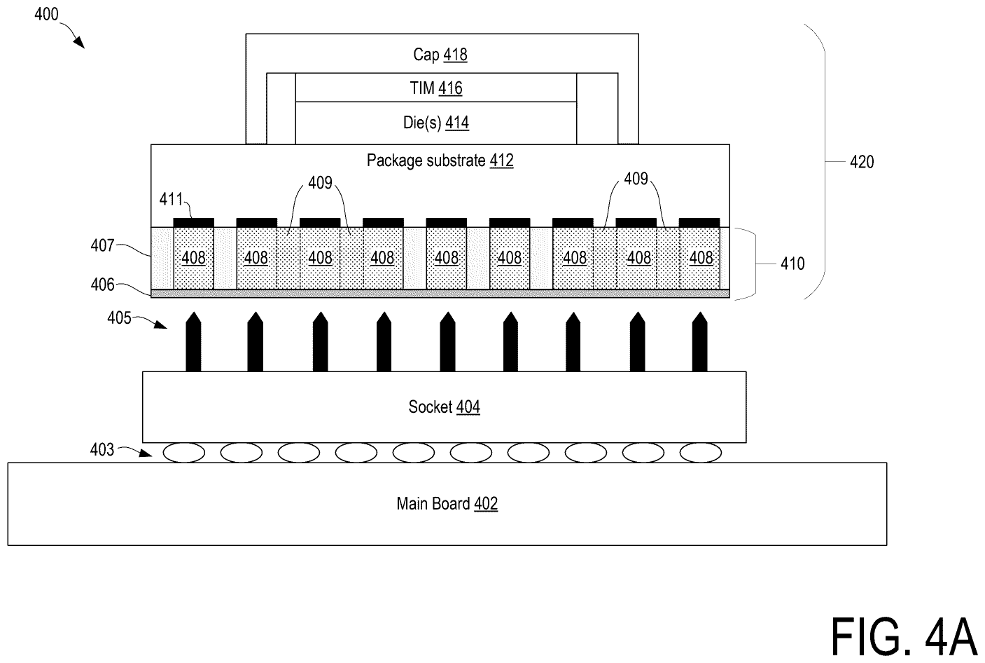

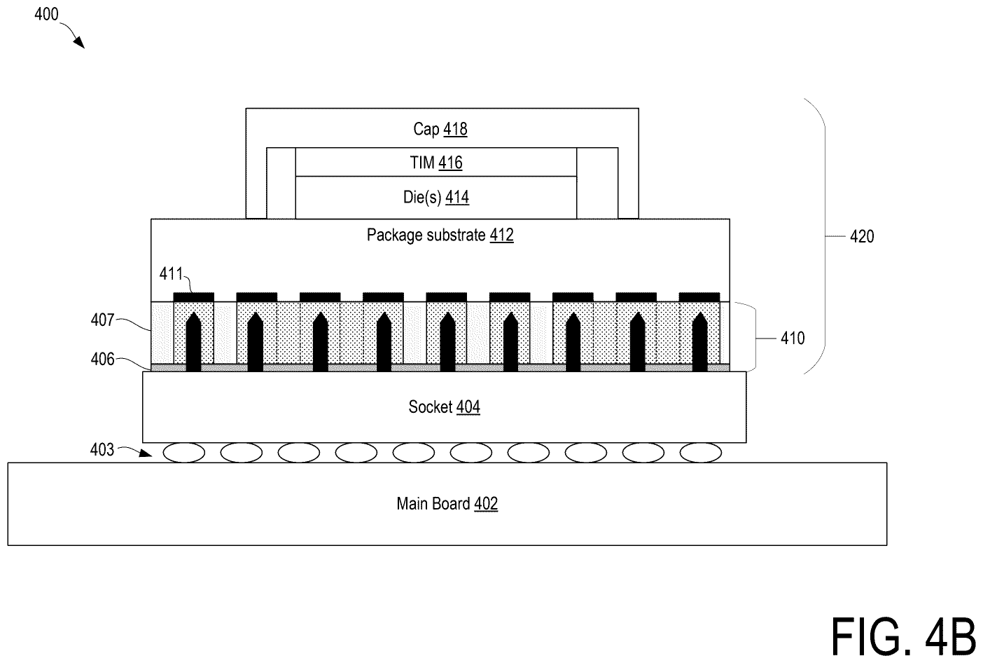

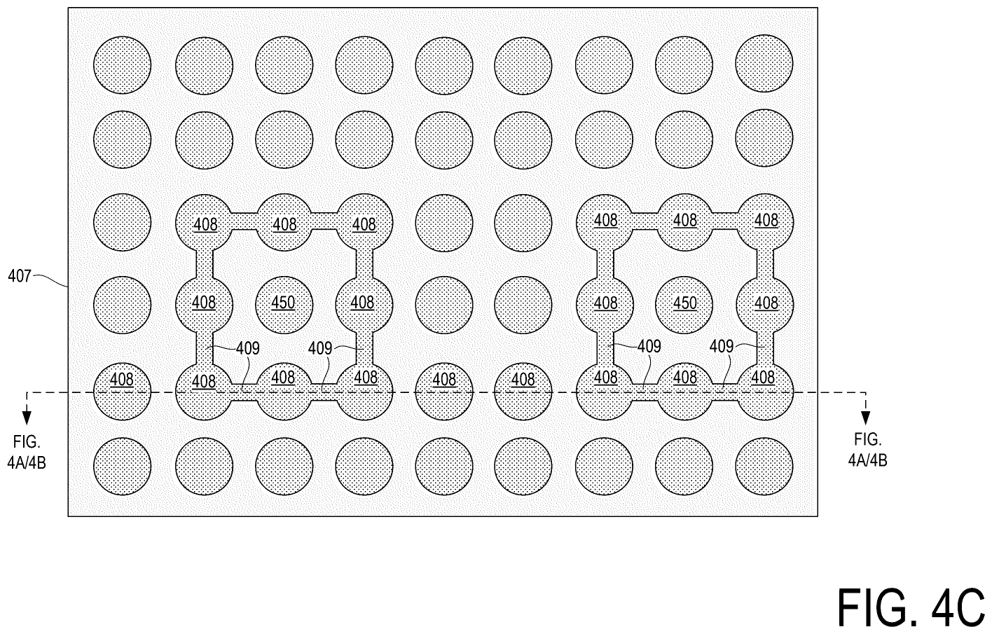

FIGS. 4A-4C illustrate yet another example integrated circuit device assembly 400 that utilizes a LM socket interconnect with pooled wells in accordance with embodiments of the present disclosure. The components of the example assembly 400 may be the same as or similar to the same respective components described above with respect to the assembly 100 of FIGS. 1A-1B, except that the layer 407 includes LM wells 408 that are pooled together via channels 409. That is, the main board 402 may be implemented in the same or similar manner as the main board 102, the bumps 403 may be implemented in the same or similar manner as the bumps 103, the socket 404 may be implemented in the same or similar manner as the socket 104, the pins 405 may be implemented in the same or similar manner as the pins 105, the layer 407 may be implemented in the same or similar manner as the layer 107, the package substrate 412 may be implemented in the same or similar manner as the package substrate 112 (with the pads 411 of the substrate 412 being implemented in the same or similar manner as the pads 111), the die 414 may be implemented in the same or similar manner as the die 114, the TIM 416 may be implemented in the same or similar manner as the TIM 116, and the cap 418 may be implemented in the same or similar manner as the cap 118.

In the example shown, the integrated circuit device package 420 includes an interposer housing 410 with a layer 407 that includes the same layout of LM wells 408 (covered by a barrier 406) as those shown in FIGS. 3A-3C, except that certain LM wells 408 are joined or pooled together via channels 409 that are the same depth as the layer 407 (in comparison with the channels 309 having depths less than the thickness of the layer 307 in the previous example).

Embodiments such as the one shown in FIGS. 4A-4C may be similarly useful to provide shielding to certain pins of the LM-interconnect, e.g., to prevent electromagnetic interference. For instance, in the example shown, the pins that would connect to the wells 450 as shown in FIG. 4C may be shielded by the surrounding wells 408 that are pooled via channels 409. As in the previous example, although the wells 408 are shown as having circular cross-sections, they may be formed in another manner, e.g., with square or rectangular cross-sections. Similarly, although the channels 409 are shown as having a particular cross-section, width with respect to the wells, or depth within the layer 407, the channels 409 may be formed in another manner.

Although the examples above are described as having an LM interposer housing (e.g., 210, 310, 410) coupled to the bottom of a package substrate (e.g., 212, 312, 412) and a socket with pins, other embodiments of the present disclosure can be implemented with pins attached to the package substrate that are inserted into LM wells of a socket.

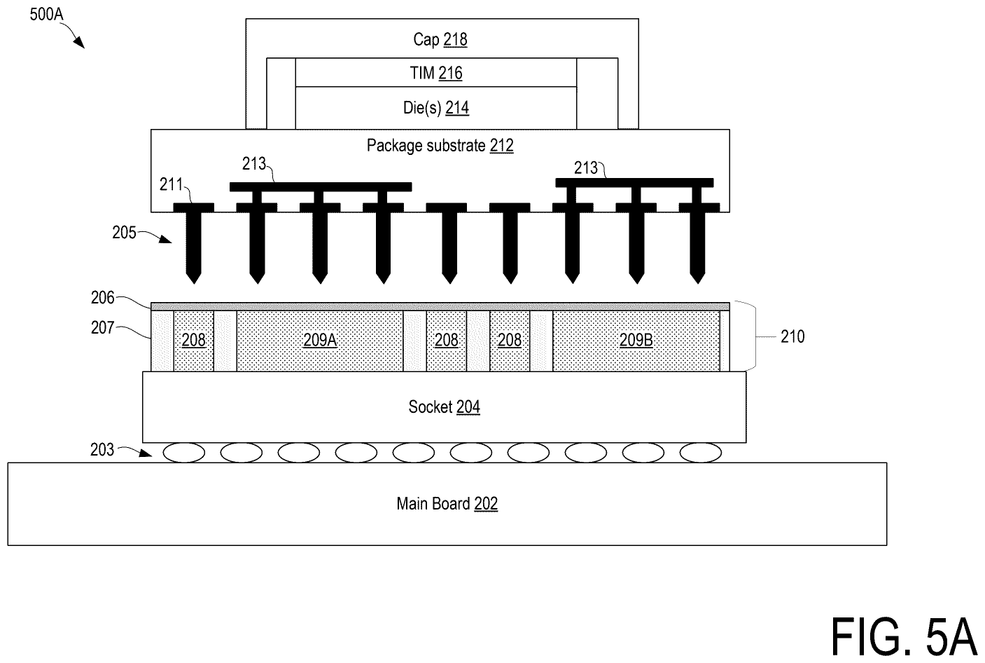

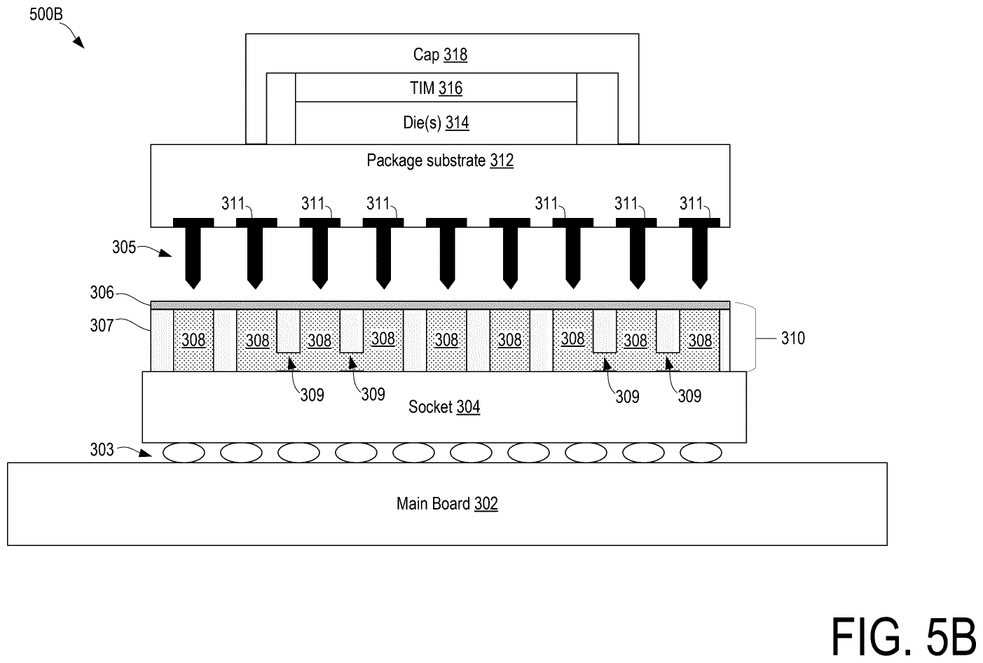

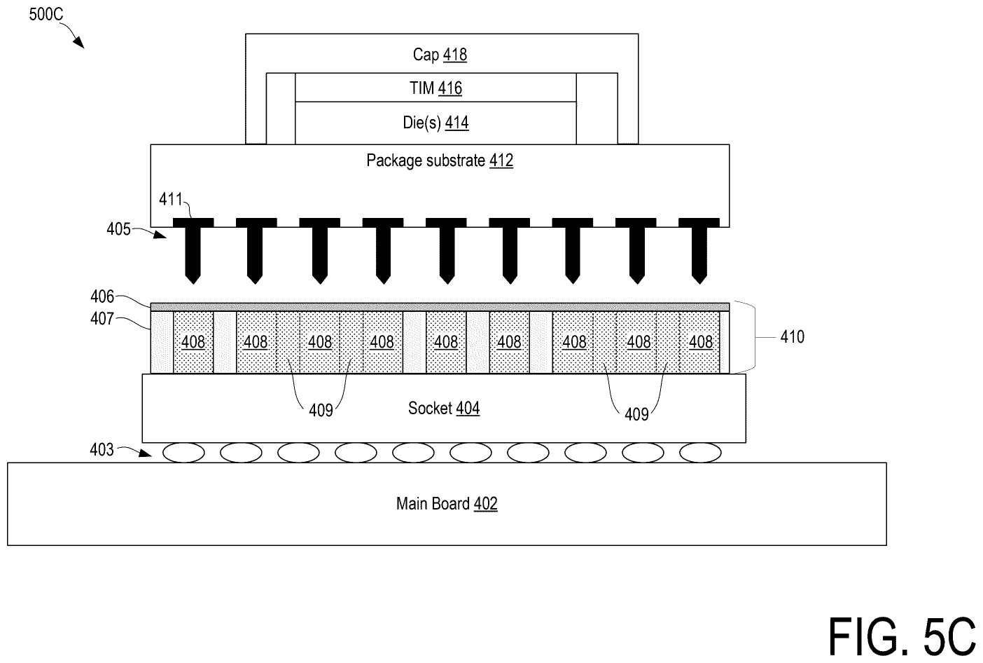

FIGS. 5A-5C illustrate example alternate embodiments of the integrated circuit device assemblies in accordance with embodiments of the present disclosure. In particular, FIG. 5A illustrates an assembly 500A that includes the same components as the assembly 200 of FIGS. 2A-2C, but with the LM wells 208, 209 being in an interposer housing 210 that is coupled to the socket 204 instead of the package substrate 212, FIG. 5B illustrates an assembly 500B that includes the same components as the assembly 300 of FIGS. 3A-3C, but with the LM wells 308 and channels 309 being in an interposer housing 310 that is coupled to the socket 304 instead of the package substrate 312, and FIG. 5C illustrates an assembly 500C that includes the same components as the assembly 400 of FIGS. 4A-4C, but with the LM wells 408 and channels 409 being in an interposer housing 410 that is coupled to the socket 404 instead of the package substrate 412.

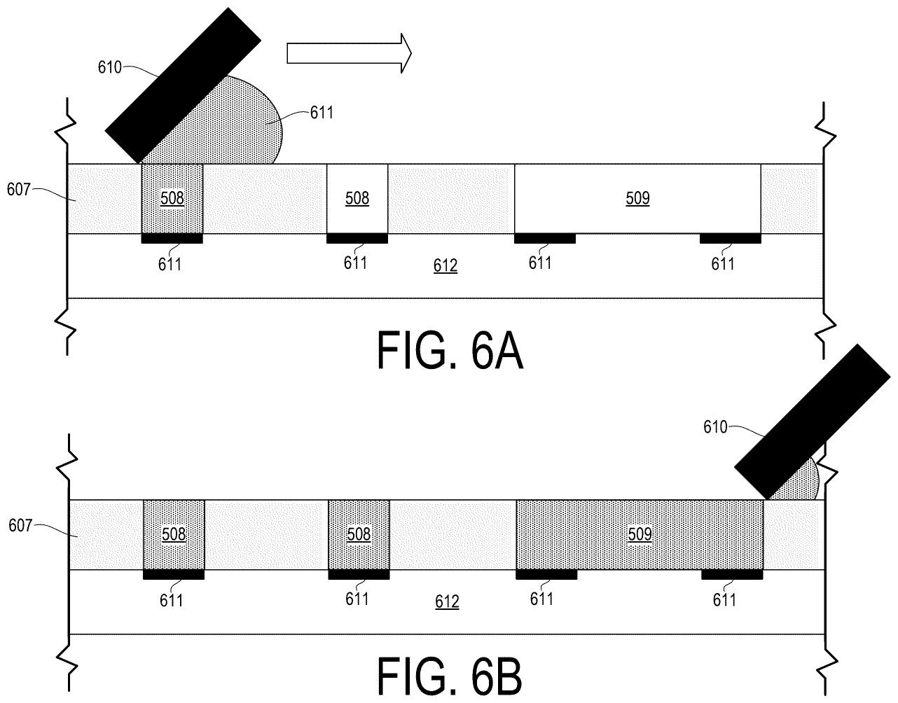

Liquid metal can be filled into the wells of the above example architectures using any suitable technique. For example, FIGS. 6A-6B illustrate an example squeegee filling process for filling an interposer with LM in accordance with embodiments of the present disclosure. In the example process, a mass of LM 611 (which may be in a paste or paste-like consistency) is spread across the layer 607 by a squeegee 610 to fill the wells 608, 609. Each well 608 is defined around a single conductive contact (or pad) 611, while the well 609 is defined around multiple contacts 611. The wells may be of different sizes (e.g., as shown in FIG. 2C) This process can be particularly useful for filling networks of wells connected by channels, e.g., as shown in FIGS. 3A-3C (e.g., where the channels are not immediately at the upper surface of the layer 607).

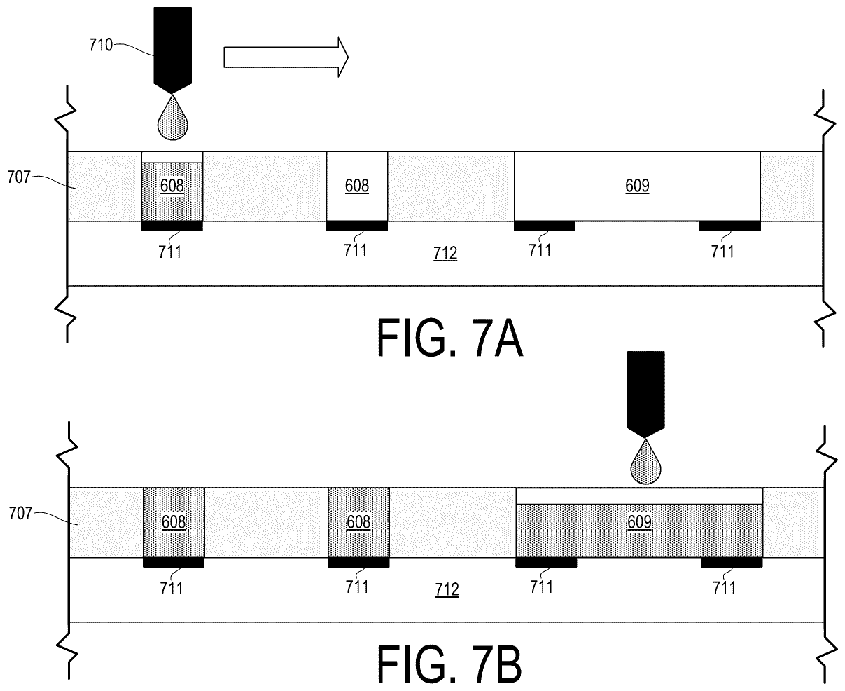

As another example, FIGS. 7A-7B illustrate an example injection filling process for filling an interposer with LM in accordance with embodiments of the present disclosure. In the example shown, an injection printer 710 fills each well 708, 709 individually, and can fill the wells regardless of their respective sizes. As in the previous example, each well 708 is defined around a single conductive contact (or pad) 711, while the well 709 is defined around multiple contacts 711.

In either example, the layer 607 or 707 can be formed using any suitable process before being attached to the package substrate 612 or 712, respectively. In some embodiments, the layers 607, 707 are formed using an injection molding process (e.g., a liquid crystal polymer), while other embodiments may use three-dimensional printing techniques to form the layers 607, 707.

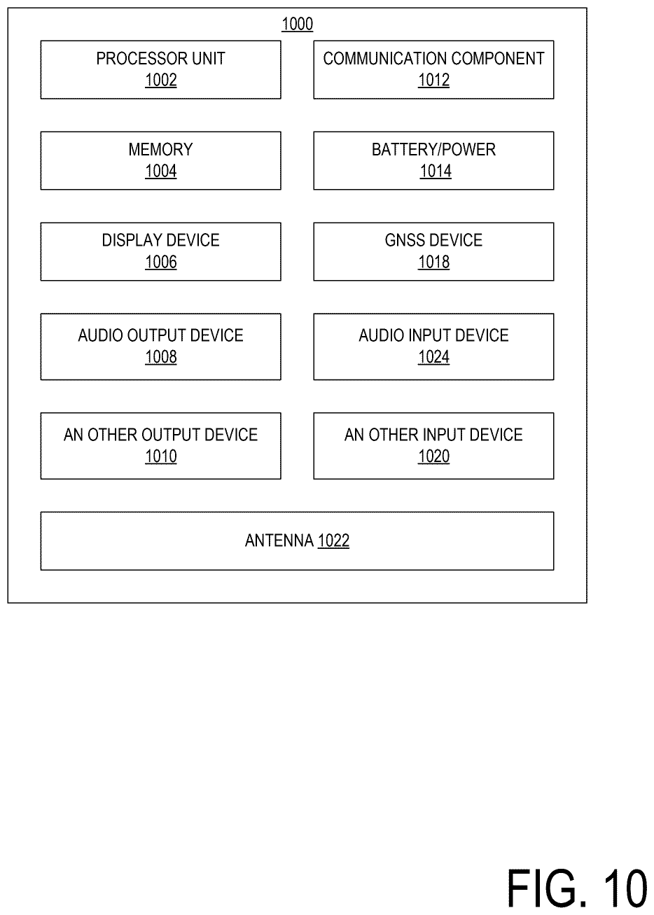

FIG. 8 is a top view of a wafer 800 and dies 802 that may incorporate any of the embodiments disclosed herein. The wafer 800 may be composed of semiconductor material and may include one or more dies 802 having integrated circuit structures formed on a surface of the wafer 800. The individual dies 802 may be a repeating unit of an integrated circuit product that includes any suitable integrated circuit. After the fabrication of the semiconductor product is complete, the wafer 800 may undergo a singulation process in which the dies 802 are separated from one another to provide discrete “chips” of the integrated circuit product. The die 802 may include one or more transistors (e.g., some of the transistors 940 of FIG. 9, discussed below), supporting circuitry to route electrical signals to the transistors, passive components (e.g., signal traces, resistors, capacitors, or inductors), and/or any other integrated circuit components. In some embodiments, the wafer 800 or the die 802 may include a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuit element. Multiple ones of these devices may be combined on a single die 802. For example, a memory array formed by multiple memory devices may be formed on a same die 802 as a processor unit (e.g., the processor unit 1002 of FIG. 10) or other logic that is configured to store information in the memory devices or execute instructions stored in the memory array.

FIG. 9 is a cross-sectional side view of an integrated circuit device 900 that may be included in any of the embodiments disclosed herein. One or more of the integrated circuit devices 900 may be included in one or more dies 802 (FIG. 8). The integrated circuit device 900 may be formed on a die substrate 902 (e.g., the wafer 800 of FIG. 8) and may be included in a die (e.g., the die 802 of FIG. 8). The die substrate 902 may be a semiconductor substrate composed of semiconductor material systems including, for example, n-type or p-type materials systems (or a combination of both). The die substrate 902 may include, for example, a crystalline substrate formed using a bulk silicon or a silicon-on-insulator (SOI) substructure. In some embodiments, the die substrate 902 may be formed using alternative materials, which may or may not be combined with silicon, that include, but are not limited to, germanium, indium antimonide, lead telluride, indium arsenide, indium phosphide, gallium arsenide, or gallium antimonide. Further materials classified as group II-VI, III-V, or IV may also be used to form the die substrate 902. Although a few examples of materials from which the die substrate 902 may be formed are described here, any material that may serve as a foundation for an integrated circuit device 900 may be used. The die substrate 902 may be part of a singulated die (e.g., the dies 802 of FIG. 8) or a wafer (e.g., the wafer 800 of FIG. 8).

The integrated circuit device 900 may include one or more device layers 904 disposed on the die substrate 902. The device layer 904 may include features of one or more transistors 940 (e.g., metal oxide semiconductor field-effect transistors (MOSFETs)) formed on the die substrate 902. The transistors 940 may include, for example, one or more source and/or drain (S/D) regions 920, a gate 922 to control current flow between the S/D regions 920, and one or more S/D contacts 924 to route electrical signals to/from the S/D regions 920. The transistors 940 may include additional features not depicted for the sake of clarity, such as device isolation regions, gate contacts, and the like. The transistors 940 are not limited to the type and configuration depicted in FIG. 9 and may include a wide variety of other types and configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon, nanosheet, or nanowire transistors.

Returning to FIG. 9, a transistor 940 may include a gate 922 formed of at least two layers, a gate dielectric and a gate electrode. The gate dielectric may include one layer or a stack of layers. The one or more layers may include silicon oxide, silicon dioxide, silicon carbide, and/or a high-k dielectric material.

The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 940 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer.

For a PMOS transistor, metals that may be used for the gate electrode include, but are not limited to, ruthenium, palladium, platinum, cobalt, nickel, conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 940 along the source-channel-drain direction, the gate electrode may consist of a U-shaped structure that includes a bottom portion substantially parallel to the surface of the die substrate 902 and two sidewall portions that are substantially perpendicular to the top surface of the die substrate 902. In other embodiments, at least one of the metal layers that form the gate electrode may simply be a planar layer that is substantially parallel to the top surface of the die substrate 902 and does not include sidewall portions substantially perpendicular to the top surface of the die substrate 902. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 920 may be formed within the die substrate 902 adjacent to the gate 922 of individual transistors 940. The S/D regions 920 may be formed using an implantation/diffusion process or an etching/deposition process, for example. In the former process, dopants such as boron, aluminum, antimony, phosphorous, or arsenic may be ion-implanted into the die substrate 902 to form the S/D regions 920. An annealing process that activates the dopants and causes them to diffuse farther into the die substrate 902 may follow the ion-implantation process. In the latter process, the die substrate 902 may first be etched to form recesses at the locations of the S/D regions 920. An epitaxial deposition process may then be carried out to fill the recesses with material that is used to fabricate the S/D regions 920. In some implementations, the S/D regions 920 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 920 may be formed using one or more alternate semiconductor materials such as germanium or a group III-V material or alloy. In further embodiments, one or more layers of metal and/or metal alloys may be used to form the S/D regions 920.

Electrical signals, such as power and/or input/output (I/O) signals, may be routed to and/or from the devices (e.g., transistors 940) of the device layer 904 through one or more interconnect layers disposed on the device layer 904 (illustrated in FIG. 9 as interconnect layers 906-910). For example, electrically conductive features of the device layer 904 (e.g., the gate 922 and the S/D contacts 924) may be electrically coupled with the interconnect structures 928 of the interconnect layers 906-910. The one or more interconnect layers 906-910 may form a metallization stack (also referred to as an “ILD stack”) 919 of the integrated circuit device 900.

The interconnect structures 928 may be arranged within the interconnect layers 906-910 to route electrical signals according to a wide variety of designs; in particular, the arrangement is not limited to the particular configuration of interconnect structures 928 depicted in FIG. 9. Although a particular number of interconnect layers 906-910 is depicted in FIG. 9, embodiments of the present disclosure include integrated circuit devices having more or fewer interconnect layers than depicted.

In some embodiments, the interconnect structures 928 may include lines 928a and/or vias 928b filled with an electrically conductive material such as a metal. The lines 928a may be arranged to route electrical signals in a direction of a plane that is substantially parallel with a surface of the die substrate 902 upon which the device layer 904 is formed. For example, the lines 928a may route electrical signals in a direction in and out of the page and/or in a direction across the page from the perspective of FIG. 9. The vias 928b may be arranged to route electrical signals in a direction of a plane that is substantially perpendicular to the surface of the die substrate 902 upon which the device layer 904 is formed. In some embodiments, the vias 928b may electrically couple lines 928a of different interconnect layers 906-910 together.

The interconnect layers 906-910 may include a dielectric material 926 disposed between the interconnect structures 928, as shown in FIG. 9. In some embodiments, dielectric material 926 disposed between the interconnect structures 928 in different ones of the interconnect layers 906-910 may have different compositions; in other embodiments, the composition of the dielectric material 926 between different interconnect layers 906-910 may be the same. The device layer 904 may include a dielectric material 926 disposed between the transistors 940 and a bottom layer of the metallization stack as well. The dielectric material 926 included in the device layer 904 may have a different composition than the dielectric material 926 included in the interconnect layers 906-910; in other embodiments, the composition of the dielectric material 926 in the device layer 904 may be the same as a dielectric material 926 included in any one of the interconnect layers 906-910.

A first interconnect layer 906 (referred to as Metal 1 or “M1”) may be formed directly on the device layer 904. In some embodiments, the first interconnect layer 906 may include lines 928a and/or vias 928b, as shown. The lines 928a of the first interconnect layer 906 may be coupled with contacts (e.g., the S/D contacts 924) of the device layer 904. The vias 928b of the first interconnect layer 906 may be coupled with the lines 928a of a second interconnect layer 908.

The second interconnect layer 908 (referred to as Metal 2 or “M2”) may be formed directly on the first interconnect layer 906. In some embodiments, the second interconnect layer 908 may include via 928b to couple the lines 928 of the second interconnect layer 908 with the lines 928a of a third interconnect layer 910. Although the lines 928a and the vias 928b are structurally delineated with a line within individual interconnect layers for the sake of clarity, the lines 928a and the vias 928b may be structurally and/or materially contiguous (e.g., simultaneously filled during a dual-damascene process) in some embodiments.

The third interconnect layer 910 (referred to as Metal 3 or “M3”) (and additional interconnect layers, as desired) may be formed in succession on the second interconnect layer 908 according to similar techniques and configurations described in connection with the second interconnect layer 908 or the first interconnect layer 906. In some embodiments, the interconnect layers that are “higher up” in the metallization stack 919 in the integrated circuit device 900 (i.e., farther away from the device layer 904) may be thicker that the interconnect layers that are lower in the metallization stack 919, with lines 928a and vias 928b in the higher interconnect layers being thicker than those in the lower interconnect layers.

The integrated circuit device 900 may include a solder resist material 934 (e.g., polyimide or similar material) and one or more conductive contacts 936 formed on the interconnect layers 906-910. In FIG. 9, the conductive contacts 936 are illustrated as taking the form of bond pads. The conductive contacts 936 may be electrically coupled with the interconnect structures 928 and configured to route the electrical signals of the transistor(s) 940 to external devices. For example, solder bonds may be formed on the one or more conductive contacts 936 to mechanically and/or electrically couple an integrated circuit die including the integrated circuit device 900 with another component (e.g., a printed circuit board or a package substrate, e.g., 112). The integrated circuit device 900 may include additional or alternate structures to route the electrical signals from the interconnect layers 906-910; for example, the conductive contacts 936 may include other analogous features (e.g., posts) that route the electrical signals to external components.

In some embodiments in which the integrated circuit device 900 is a double-sided die, the integrated circuit device 900 may include another metallization stack (not shown) on the opposite side of the device layer(s) 904. This metallization stack may include multiple interconnect layers as discussed above with reference to the interconnect layers 906-910, to provide conductive pathways (e.g., including conductive lines and vias) between the device layer(s) 904 and additional conductive contacts (not shown) on the opposite side of the integrated circuit device 900 from the conductive contacts 936.

In other embodiments in which the integrated circuit device 900 is a double-sided die, the integrated circuit device 900 may include one or more through silicon vias (TSVs) through the die substrate 902; these TSVs may make contact with the device layer(s) 904, and may provide conductive pathways between the device layer(s) 904 and additional conductive contacts (not shown) on the opposite side of the integrated circuit device 900 from the conductive contacts 936. In some embodiments, TSVs extending through the substrate can be used for routing power and ground signals from conductive contacts on the opposite side of the integrated circuit device 900 from the conductive contacts 936 to the transistors 940 and any other components integrated into the die 900, and the metallization stack 919 can be used to route I/O signals from the conductive contacts 936 to transistors 940 and any other components integrated into the die 900.

Multiple integrated circuit devices 900 may be stacked with one or more TSVs in the individual stacked devices providing connection between one of the devices to any of the other devices in the stack. For example, one or more high-bandwidth memory (HBM) integrated circuit dies can be stacked on top of a base integrated circuit die and TSVs in the HBM dies can provide connection between the individual HBM and the base integrated circuit die. Conductive contacts can provide additional connections between adjacent integrated circuit dies in the stack. In some embodiments, the conductive contacts can be fine-pitch solder bumps (microbumps).

FIG. 10 is a block diagram of an example electrical device 1000 that may include one or more of the embodiments disclosed herein. For example, any suitable ones of the components of the electrical device 1000 may include one or more of assemblies 100, integrated circuit devices 900, or integrated circuit dies 802 disclosed herein. A number of components are illustrated in FIG. 10 as included in the electrical device 1000, but any one or more of these components may be omitted or duplicated, as suitable for the application. In some embodiments, some or all of the components included in the electrical device 1000 may be attached to one or more motherboards mainboards, or system boards. In some embodiments, one or more of these components are fabricated onto a single system-on-a-chip (SoC) die.

Additionally, in various embodiments, the electrical device 1000 may not include one or more of the components illustrated in FIG. 10, but the electrical device 1000 may include interface circuitry for coupling to the one or more components. For example, the electrical device 1000 may not include a display device 1006, but may include display device interface circuitry (e.g., a connector and driver circuitry) to which a display device 1006 may be coupled. In another set of examples, the electrical device 1000 may not include an audio input device 1024 or an audio output device 1008, but may include audio input or output device interface circuitry (e.g., connectors and supporting circuitry) to which an audio input device 1024 or audio output device 1008 may be coupled.

The electrical device 1000 may include one or more processor units 1002 (e.g., one or more processor units). As used herein, the terms “processor unit”, “processing unit” or “processor” may refer to any device or portion of a device that processes electronic data from registers and/or memory to transform that electronic data into other electronic data that may be stored in registers and/or memory. The processor unit 1002 may include one or more digital signal processors (DSPs), application-specific integrated circuits (ASICs), central processing units (CPUs), graphics processing units (GPUs), general-purpose GPUs (GPGPUs), accelerated processing units (APUs), field-programmable gate arrays (FPGAs), neural network processing units (NPUs), data processor units (DPUs), accelerators (e.g., graphics accelerator, compression accelerator, artificial intelligence accelerator), controller cryptoprocessors (specialized processors that execute cryptographic algorithms within hardware), server processors, controllers, or any other suitable type of processor units. As such, the processor unit can be referred to as an XPU (or xPU).

The electrical device 1000 may include a memory 1004, which may itself include one or more memory devices such as volatile memory (e.g., dynamic random access memory (DRAM), static random-access memory (SRAM)), non-volatile memory (e.g., read-only memory (ROM), flash memory, chalcogenide-based phase-change non-voltage memories), solid state memory, and/or a hard drive. In some embodiments, the memory 1004 may include memory that is located on the same integrated circuit die as the processor unit 1002. This memory may be used as cache memory (e.g., Level 1 (L1), Level 2 (L2), Level 3 (L3), Level 4 (L4), Last Level Cache (LLC)) and may include embedded dynamic random access memory (eDRAM) or spin transfer torque magnetic random access memory (STT-MRAM).

In some embodiments, the electrical device 1000 can comprise one or more processor units 1002 that are heterogeneous or asymmetric to another processor unit 1002 in the electrical device 1000. There can be a variety of differences between the processing units 1002 in a system in terms of a spectrum of metrics of merit including architectural, microarchitectural, thermal, power consumption characteristics, and the like. These differences can effectively manifest themselves as asymmetry and heterogeneity among the processor units 1002 in the electrical device 1000.

In some embodiments, the electrical device 1000 may include a communication component 1012 (e.g., one or more communication components). For example, the communication component 1012 can manage wireless communications for the transfer of data to and from the electrical device 1000. The term “wireless” and its derivatives may be used to describe circuits, devices, systems, methods, techniques, communications channels, etc., that may communicate data through the use of modulated electromagnetic radiation through a nonsolid medium. The term “wireless” does not imply that the associated devices do not contain any wires, although in some embodiments they might not.

The communication component 1012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication component 1012 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication component 1012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication component 1012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication component 1012 may operate in accordance with other wireless protocols in other embodiments. The electrical device 1000 may include an antenna 1022 to facilitate wireless communications and/or to receive other wireless communications (such as AM or FM radio transmissions).

In some embodiments, the communication component 1012 may manage wired communications, such as electrical, optical, or any other suitable communication protocols (e.g., IEEE 802.3 Ethernet standards). As noted above, the communication component 1012 may include multiple communication components. For instance, a first communication component 1012 may be dedicated to shorter-range wireless communications such as Wi-Fi or Bluetooth, and a second communication component 1012 may be dedicated to longer-range wireless communications such as global positioning system (GPS), EDGE, GPRS, CDMA, WiMAX, LTE, EV-DO, or others. In some embodiments, a first communication component 1012 may be dedicated to wireless communications, and a second communication component 1012 may be dedicated to wired communications.

The electrical device 1000 may include battery/power supply circuitry 1014. The battery/power supply circuitry 1014 may include one or more energy storage devices (e.g., batteries or capacitors) and/or circuitry for coupling components of the electrical device 1000 to an energy source separate from the electrical device 1000 (e.g., AC line power).

The electrical device 1000 may include a display device 1006 (or corresponding interface circuitry, as discussed above). The display device 1006 may include one or more embedded or wired or wirelessly connected external visual indicators, such as a heads-up display, a computer monitor, a projector, a touchscreen display, a liquid crystal display (LCD), a light-emitting diode display, or a flat panel display.

The electrical device 1000 may include an audio output device 1008 (or corresponding interface circuitry, as discussed above). The audio output device 1008 may include any embedded or wired or wirelessly connected external device that generates an audible indicator, such speakers, headsets, or earbuds.

The electrical device 1000 may include an audio input device 1024 (or corresponding interface circuitry, as discussed above). The audio input device 1024 may include any embedded or wired or wirelessly connected device that generates a signal representative of a sound, such as microphones, microphone arrays, or digital instruments (e.g., instruments having a musical instrument digital interface (MIDI) output). The electrical device 1000 may include a Global Navigation Satellite System (GNSS) device 1018 (or corresponding interface circuitry, as discussed above), such as a Global Positioning System (GPS) device. The GNSS device 1018 may be in communication with a satellite-based system and may determine a geolocation of the electrical device 1000 based on information received from one or more GNSS satellites, as known in the art.

The electrical device 1000 may include another output device 1010 (or corresponding interface circuitry, as discussed above). Examples of the other output device 1010 may include an audio codec, a video codec, a printer, a wired or wireless transmitter for providing information to other devices, or an additional storage device.

The electrical device 1000 may include another input device 1020 (or corresponding interface circuitry, as discussed above). Examples of the other input device 1020 may include an accelerometer, a gyroscope, a compass, an image capture device (e.g., monoscopic or stereoscopic camera), a trackball, a trackpad, a touchpad, a keyboard, a cursor control device such as a mouse, a stylus, a touchscreen, proximity sensor, microphone, a bar code reader, a Quick Response (QR) code reader, electrocardiogram (ECG) sensor, PPG (photoplethysmogram) sensor, galvanic skin response sensor, any other sensor, or a radio frequency identification (RFID) reader.

The electrical device 1000 may have any desired form factor, such as a hand-held or mobile electrical device (e.g., a cell phone, a smart phone, a mobile internet device, a music player, a tablet computer, a laptop computer, a 2-in-1 convertible computer, a portable all-in-one computer, a netbook computer, an ultrabook computer, a personal digital assistant (PDA), an ultra mobile personal computer, a portable gaming console, etc.), a desktop electrical device, a server, a rack-level computing solution (e.g., blade, tray or sled computing systems), a workstation or other networked computing component, a printer, a scanner, a monitor, a set-top box, an entertainment control unit, a stationary gaming console, smart television, a vehicle control unit, a digital camera, a digital video recorder, a wearable electrical device or an embedded computing system (e.g., computing systems that are part of a vehicle, smart home appliance, consumer electronics product or equipment, manufacturing equipment). In some embodiments, the electrical device 1000 may be any other electronic device that processes data. In some embodiments, the electrical device 1000 may comprise multiple discrete physical components. Given the range of devices that the electrical device 1000 can be manifested as in various embodiments, in some embodiments, the electrical device 1000 can be referred to as a computing device or a computing system.

Illustrative examples of the technologies described throughout this disclosure are provided below. Embodiments of these technologies may include any one or more, and any combination of, the examples described below. In some embodiments, at least one of the systems or components set forth in one or more of the preceding figures may be configured to perform one or more operations, techniques, processes, and/or methods as set forth in the following examples.

Example 1 is an apparatus comprising: a substrate comprising conductive contacts on a first side of the substrate; a housing coupled to the first side of the substrate, the housing defining a plurality of holes comprising first holes defined around one conductive contact of the substrate and a second hole defined around a plurality of conductive contacts of the substrate; and Gallium-based liquid metal in each hole defined by the housing, the liquid metal in contact with the conductive contact in the hole.

Example 2 includes the subject matter of Example 1, wherein the first holes have circular cross-sections and the second hole has a rectangular cross-section.

Example 3 includes the subject matter of any one of Examples 1-2, wherein the second hole is defined around a first plurality of conductive contacts of the substrate and the apparatus further comprises a third hole defined around a second plurality of conductive contacts of the substrate.

Example 4 includes the subject matter of Example 3, wherein the first plurality of conductive contacts is greater than the second plurality of conductive contacts.

Example 5 includes the subject matter of any one of Examples 1-4, further comprising an integrated circuit die coupled to the substrate on a second side of the substrate opposite the first side of the substrate.

Example 6 includes the subject matter of any one of Examples 1-5, further comprising a socket comprising pins extending from the socket into the holes of the housing, wherein a subset of the pins are in the same hole of the housing.

Example 7 is an apparatus comprising: a substrate comprising conductive contacts on a first side of the substrate; a housing coupled to the first side of the substrate, the housing defining a plurality of holes at least substantially defined around respective conductive contacts of the substrate, the housing further defining channels between a subset of the holes; and Gallium-based liquid metal in each hole and channel defined by the housing, the liquid metal in contact with the conductive contact in the hole.

Example 8 includes the subject matter of Example 7, wherein a depth of the channels is less than a depth of the housing.

Example 8.5 includes the subject matter of Example 8, wherein the channels are adjacent to the substrate.

Example 9 includes the subject matter of Example 7, wherein a depth of the channels is the same as a depth of the housing.

Example 10 includes the subject matter of any one of Examples 7-9, wherein the subset of the holes having channels defined therebetween are around another hole defined by the housing.

Example 11 includes the subject matter of any one of Examples 7-10, wherein the plurality of holes have circular cross-sections.

Example 12 includes the subject matter of any one of Examples 7-11, further comprising an integrated circuit die coupled to the substrate on a second side of the substrate opposite the first side of the substrate.

Example 13 includes the subject matter of any one of Examples 7-12, further comprising a socket comprising pins extending from the socket into respective holes of the housing, wherein the pins in the subset of the holes connected by the channels are in electrical contact with one another via the liquid metal in the channels.

Example 14 is a system comprising: a main circuit board; a socket coupled to the main circuit board, the socket comprising pins extending from the socket in a direction opposite the main circuit board; and an integrated circuit device package coupled to the socket, the integrated circuit device package comprising: a substrate; an integrated circuit device coupled to a first side of the substrate; a plurality of wells on a second side of the substrate opposite the first side, each well having Gallium-based liquid metal therein, wherein the wells comprise at least one well with liquid metal conductively coupled to a plurality of conductive contacts of the substrate; and wherein the pins of the socket are in contact with the liquid metal in the wells.

Example 15 includes the subject matter of Example 14, wherein the wells comprise: first wells, each first well defined around a respective conductive contact of the substrate; and a second well defined around a plurality of conductive contacts of the substrate.

Example 16 includes the subject matter of Example 14, wherein the wells are substantially defined around respective conductive contacts of the substrate and the package further comprises channels between a subset of the wells.

Example 17 includes the subject matter of Example 16, wherein the subset of the wells having channels therebetween are around another well.

Example 18 includes the subject matter of any one of Examples 14-17, further comprising power supply circuitry connected to the main circuit board, the power supply circuitry connected to the integrated circuit device via the well defined around a plurality of conductive contacts.

Example 19 includes the subject matter of Example 18, wherein a power supply voltage is connected to the integrated circuit device via the well defined around a plurality of conductive contacts.

Example 20 includes the subject matter of Example 18, wherein a ground signal is connected to the integrated circuit device via the well defined around a plurality of conductive contacts.

Example 21 is apparatus comprising: a substrate comprising a first conductive contact, a second conductive contact, and a third conductive contact on a first side of the substrate; a housing having a first side and a second side opposite the first side, the second side of the housing adjacent to the first side of the substrate, the housing comprising: a first opening extending from the first side of the housing to the second side of the housing, the first opening adjacent to the first conductive contact; and a second opening extending from the first side of the housing to the second side of the housing, the second opening adjacent to the second conductive contact and the third conductive contact; and metal comprising Gallium in the first opening and in the second opening, wherein the metal in the first opening is in conductively coupled to the first conductive contact and the metal in the second opening is conductively coupled to the second conductive contact and the third conductive contact.

Example 22 includes the subject matter of Example 21, wherein the first opening has a circular cross-section and the second opening has a rectangular or square cross-section.

Example 23 includes the subject matter of Example 21, wherein the second opening comprises a first portion adjacent to a first conductive contact of the substrate, a second portion adjacent to a second conductive contact of the substrate, and a channel extending between the first portion and the second portion.

Example 24 includes the subject matter of Example 23, wherein the channel is adjacent to the first side of the substrate and is not adjacent to the first side of the housing.

Example 25 includes the subject matter of any one of Examples 21-24, further comprising an integrated circuit die coupled to the substrate on a second side of the substrate opposite the first side of the substrate.

Example 26 includes the subject matter of any one of Examples 21-25, wherein the substrate is a first substrate and the apparatus further comprises a second substrate comprising a first pin extending into the first opening and in contact with the metal in the first opening, a second pin extending into the second opening and in contact with the metal in the second opening, and a third pin extending into the second opening and in contact with the metal in the second opening.

Example 27 is a an apparatus comprising: substrate comprising conductive contacts on a first side of the substrate; a housing having a first side adjacent to the first side of the substrate and a second side opposite the first side, the housing defining a plurality of openings at least substantially around respective conductive contacts of the substrate, and further defining a channel between at least two of the openings; and liquid metal comprising Gallium in the openings and in the channel, the liquid metal in contact with the conductive contacts in the openings.

Example 28 includes the subject matter of Example 27, wherein a depth of the channel is less than a depth of the housing.

Example 29 includes the subject matter of Example 28, wherein the channel is adjacent to the first side of the substrate.

Example 30 includes the subject matter of Example 27, wherein a depth of the channel is the same as a depth of the housing.

Example 31 includes the subject matter of any one of Examples 27-30, wherein the housing defines a first opening and second openings around the first opening, and channels connecting the second openings.

Example 32 includes the subject matter of any one of Examples 27-31, further comprising an integrated circuit die coupled to the substrate on a second side of the substrate opposite the first side of the substrate.

Example 33 includes the subject matter of any one of Examples 27-32, further comprising a socket comprising pins extending from the socket into respective openings of the housing, wherein the pins in the subset of the openings connected by the channels are in electrical contact with one another via the liquid metal in the channels.

In the above description, various aspects of the illustrative implementations have been described using terms commonly employed by those skilled in the art to convey the substance of their work to others skilled in the art. However, it will be apparent to those skilled in the art that the present disclosure may be practiced with only some of the described aspects. For purposes of explanation, specific numbers, materials, and configurations have been set forth to provide a thorough understanding of the illustrative implementations. However, it will be apparent to one skilled in the art that the present disclosure may be practiced without all of the specific details. In other instances, well-known features have been omitted or simplified in order not to obscure the illustrative implementations.

Further, concepts described herein are illustrated by way of example and not by way of limitation in the accompanying Figures. For simplicity and clarity of illustration, elements illustrated in the Figures might not be necessarily drawn to scale. Where considered appropriate, reference labels may have been repeated between certain Figures to indicate corresponding or analogous elements.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B and C).

As used herein, the phrase “located on” in the context of a first layer or component located on a second layer or component refers to the first layer or component being directly physically attached to the second part or component (no layers or components between the first and second layers or components) or physically attached to the second layer or component with one or more intervening layers or components.

As used herein, the term “adjacent” refers to layers or components that are in physical contact with each other. That is, there is no layer or component between the stated adjacent layers or components. For example, a layer X that is adjacent to a layer Y refers to a layer that is in physical contact with layer Y.

The terms “over,” “under,” “between,” “above,” and “on” as used herein may refer to a relative position of one material layer or component with respect to other layers or components. For example, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similarly, unless explicitly stated otherwise, one feature disposed between two features may be in direct contact with the adjacent features or may have one or more intervening features.

The above description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

The term “coupled with,” along with its derivatives, may be used herein. “Coupled” may mean one or more of the following. “Coupled” may mean that two or more elements are in direct physical or electrical contact. However, “coupled” may also mean that two or more elements indirectly contact each other, but yet still cooperate or interact with each other, and may mean that one or more other elements are coupled or connected between the elements that are said to be coupled with each other. The term “directly coupled” may mean that two or more elements are in direct contact.

In various embodiments, the phrase “a first feature formed, deposited, or otherwise disposed on a second feature” may mean that the first feature is formed, deposited, or disposed over the second feature, and at least a part of the first feature may be in direct contact (e.g., direct physical and/or electrical contact) or indirect contact (e.g., having one or more other features between the first feature and the second feature) with at least a part of the second feature.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

1. An apparatus comprising:
a substrate comprising a first conductive contact, a second conductive contact, and a third conductive contact on a first side of the substrate;
a housing having a first side and a second side opposite the first side, the second side of the housing adjacent to the first side of the substrate, the housing comprising:
a first opening extending from the first side of the housing to the second side of the housing, the first opening adjacent to the first conductive contact; and
a second opening extending from the first side of the housing to the second side of the housing, the second opening adjacent to the second conductive contact and the third conductive contact; and
metal comprising Gallium in the first opening and in the second opening, wherein the metal in the first opening is in conductively coupled to the first conductive contact and the metal in the second opening is conductively coupled to the second conductive contact and the third conductive contact.

2. The apparatus of claim 1, wherein the first opening has a circular cross-section and the second opening has a rectangular or square cross-section.

3. The apparatus of claim 1, wherein the second opening comprises a first portion adjacent to a first conductive contact of the substrate, a second portion adjacent to a second conductive contact of the substrate, and a channel extending between the first portion and the second portion.

4. The apparatus of claim 2, wherein the channel is adjacent to the first side of the substrate and is not adjacent to the first side of the housing.

5. The apparatus of claim 1, further comprising an integrated circuit die coupled to the substrate on a second side of the substrate opposite the first side of the substrate.

6. The apparatus of claim 1, wherein the substrate is a first substrate and the apparatus further comprises a second substrate comprising a first pin extending into the first opening and in contact with the metal in the first opening, a second pin extending into the second opening and in contact with the metal in the second opening, and a third pin extending into the second opening and in contact with the metal in the second opening.

7. An apparatus comprising:
a substrate comprising conductive contacts on a first side of the substrate;
a housing having a first side adjacent to the first side of the substrate and a second side opposite the first side, the housing defining a plurality of openings at least substantially around respective conductive contacts of the substrate, and further defining a channel between at least two of the openings; and
liquid metal comprising Gallium in the openings and in the channel, the liquid metal in contact with the conductive contacts in the openings.

8. The apparatus of claim 7, wherein a depth of the channel is less than a depth of the housing.

9. The apparatus of claim 8, wherein the channel is adjacent to the first side of the substrate.

10. The apparatus of claim 7, wherein a depth of the channel is the same as a depth of the housing.

11. The apparatus of claim 7, wherein the housing defines a first opening and second openings around the first opening, and channels connecting the second openings.

12. The apparatus of claim 7, further comprising an integrated circuit die coupled to the substrate on a second side of the substrate opposite the first side of the substrate.

13. The apparatus of claim 7, further comprising a socket comprising pins extending from the socket into respective openings of the housing, wherein the pins in the subset of the openings connected by the channels are in electrical contact with one another via the liquid metal in the channels.

14. A system comprising:
a main circuit board;
a socket coupled to the main circuit board, the socket comprising pins extending from the socket in a direction opposite the main circuit board; and
an integrated circuit device package coupled to the socket, the integrated circuit device package comprising:
a substrate;
an integrated circuit device coupled to a first side of the substrate; and
a plurality of wells on a second side of the substrate opposite the first side, each well having liquid metal therein, wherein the wells comprise at least one well with liquid metal conductively coupled to a plurality of conductive contacts of the substrate;
wherein the pins of the socket are in contact with the liquid metal in the wells.

15. The system of claim 14, wherein the wells comprise:
first wells, each first well defined around a respective conductive contact of the substrate; and
a second well defined around a plurality of conductive contacts of the substrate.

16. The system of claim 14, wherein the wells are substantially defined around respective conductive contacts of the substrate and the package further comprises channels between a subset of the wells.

17. The system of claim 16, wherein the subset of the wells having channels therebetween are around another well.

18. The system of claim 14, further comprising power supply circuitry connected to the main circuit board, the power supply circuitry connected to the integrated circuit device via the well defined around a plurality of conductive contacts.

19. The system of claim 18, wherein a power supply voltage is connected to the integrated circuit device via the well defined around a plurality of conductive contacts.

20. The system of claim 18, wherein a ground signal is connected to the integrated circuit device via the well defined around a plurality of conductive contacts.
